(19) United States
(12) Patent Application Publication
(10) Pub. No.: US 2015/0027531 A1
(43) Pub. Date: Jan. 29, 2015

(54) SILICON-CONTAINING FILM AND METHOD FOR FORMING SILICON-CONTAINING FILM

(71) Applicant: TORAY ENGINEERING CO., LTD., Chuo-ku, Tokyo (JP)

(72) Inventors: Masamichi Yamashita, Otsu-shi (JP); Takayoshi Fujimoto, Otsu-shi (JP); Takashi Iwade, Otsu-shi (JP)

(73) Assignee: Toray Engineering Co., Ltd., Chuo-ku, Tokyo (JP)

(21) Appl. No.: 14/382,835

(22) PCT Filed: Jan. 16, 2013
(86) PCT No.: PCT/JP2013/050607

§ 371 Date: Sep. 4, 2014

(30) Foreign Application Priority Data
Mar. 7, 2012 (JP) 2012-050961

(51) Int. Cl. H01L 31/028; H01L 31/0224; H01L 31/18

(52) U.S. Cl. CPC H01L 31/028; H01L 31/1804; H01L 31/0224; H01L 31/022475; H01L 31/022483
USPC 136/256; 438/57

(57) ABSTRACT

A silicon-containing film includes a first chemical vapor deposition layer and a second chemical vapor deposition layer. The first chemical vapor deposition layer includes elemental silicon. The first chemical vapor deposition layer is formed by a plasma CVD method such that oxygen concentration is greater than or equal to 0% by element and less than 10% by element. The second chemical vapor deposition layer includes elemental silicon. The second chemical vapor deposition layer is formed by the plasma CVD method such that oxygen concentration is greater than 35% by element and less than or equal to 70% by element. A ratio of the thickness of the second chemical vapor deposition layer relative to the thickness of the first chemical vapor deposition layer is 1.5-9.

### CROSS-REFERENCE TO RELATED APPLICATIONS

This application is a U.S. National stage of International Application No. PCT/JP2013/050607 filed on Jan. 16, 2013. This application claims priority to Japanese Patent Application No. 2012-050961 filed with Japan Patent Office on Mar. 7, 2012. The entire disclosure of Japanese Patent Application No. 2012-050961 is hereby incorporated herein by reference.

### BACKGROUND

1. Field of the invention

The present invention relates to a silicon-containing film and a method for forming a silicon-containing film.

2. Background Information

In recent years, in thin film devices such as thin film solar cell modules, etc., a sealing film having stable barrier properties that prevents the intrusion of water into the device and in which peeling does not occur due to change over time has been in demand. A thin film solar cell module is configured by layering a transparent electrode film, a functional film (a power generation layer), and an electrode film in this order. An example of a way to maintain a stable power generating efficiency in this thin film-based solar cell module is to prevent the intrusion of water into the solar cell. That is, a solar cell has a characteristic of corroding and deteriorating when exposed to water, and the deterioration of the solar cell leads to a reduction in the power generation efficiency. As a result, for this reason, a solar cell layer, a sealing layer consisting of a thermosetting resin such as ethylene-vinyl acetate copolymer (EVA), and a protective layer that is made of polyvinyl fluoride resin or that uses a composite film comprising polyvinyl fluoride resin. Then, the sealing layer is cured by crosslinking with heating and melting and is sealed using the vacuum lamination method to configure the solar cell module, thereby preventing the intrusion of water into the solar cell with the sealing layer and the protective layer. However, even if a sealing layer and a protective layer are provided to a solar cell module, there was the problem that the prevention of the intrusion of water into the solar cell was insufficient.

That is, since weatherability of EVA, such as water resistance, moisture resistance, and alkali resistance is degraded due to light degradation, if the EVA is gradually degraded due to long-term use, water will intrude from the side surface of the solar cell module, and the solar cell will be exposed to water. When a solar cell is exposed to water, there was the problem that the power generation efficiency will decline due to the degradation of the solar cell.

WO 2007/032515 (Patent Document 1) discloses an organic electroluminescent display panel with a structure wherein, in a laminated film of inorganic material film (a barrier layer) and organic material film, the thickness of the organic material film is greater than or equal to five times the thickness of the inorganic material film. Regarding the sealing film that is used, inorganic film, such as silicon oxide (SiO₂) and silicon nitride (SiNₓ), and organic film that is film formed by the wet method are disclosed, and a laminated film configured by an organic film thickness that is greater than or equal to five times the thickness of the inorganic film is disclosed.

Here, regarding the point that the thickness of the organic film is greater than or equal to five times the thickness of the inorganic film, Patent Document 1 discloses that this is because, when the inorganic film is formed using a dry film-forming method, foreign matter is easily adhered (page 5, five lines from the top). Regarding the above, the thought is that, rather than foreign matter being easily adhered when using a dry film-forming method, the manufacturing process of the inorganic film and organic film requires the exchange of vacuum and air, requiring steps such as vacuuming and opening to the air; due to the air that flows in and out in order to change the ambient environment, foreign matter will float in, and the foreign matter will adhere to the base material; therefore, covering the foreign matter is necessary, and, thus, making thickly layering the organic film is necessary.

Japanese Laid-Open Patent Application Publication No. 2011-238355 (Patent Document 2) discloses having a range in the thermal expansion coefficient of the stress relaxation layer in order to prevent cracking due to thermal expansion. Regarding the film thickness of each layer, the disclosure explains that the thickness is preferably 30 nm-1000 nm for the gas barrier layer (paragraph 0047) and that the smoothness is good when the thickness is 1000-10000 nm (paragraph 0129) for the stress relaxation layer.

However, while the disclosure explains that the film was evaluated after 300 hours, there is no disclosure of the test environment, so the thought is that the film was evaluated in the atmosphere. Normally, when evaluating solar cells, the atmosphere is 85° C., 85% RH according to JIS C 8991; therefore, the above-described evaluation is insufficient, and from the evaluation results, the thought is that this is inferior to the JIS rating. Additionally, since a longer life is also demanded of organic EL displays, a test at the above-described 85° C., 85% RH environment is thought be necessary.

Japanese Laid-Open Patent Application Publication No. 2005-7741 (Patent Document 3) discloses a layered body of an inorganic oxide layer and an acrylic resin layer; the disclosure explains that the film thickness of the organic oxide layer is 1.0-300 nm and is, preferably, 10-150 nm (paragraph 0022) and that the thickness of the acrylic resin layer is 10 nm-10000 nm and, preferably, 200-1000 nm (paragraph 0036).

However, in the layered body described above, regarding the problem of adhesion, while the disclosure explains that the problem is solved by making the organic film thicker, so that this layer has better stress relaxation properties than the inorganic film, in the example, the evaluation was done at 40° C., 90% RH; therefore, a test in a JIS C 8991 85° C., 85% RH environment has not been conducted, and from the evaluation results, the thought is that this is inferior to the JIS rating.

Japanese Laid Open Patent Application Publication No. 2009-149170 (Patent Document 4) discloses a solar cell module 600 comprising a base material 60, a solar cell element 70 in which a transparent electrode film 61 transmits light, a power generation layer 62 that receives the light and generates electricity, and a back electrode 63 are layered on this base material in this order; additionally, there are a protective layer 66 that protects the solar cell element 70, a resin layer 65 that is made of resin and is filled between the protective layer 66 and the base material 60, and a frame 67, wherein the light is taken from the base material 60 side. The solar cell element 70 is covered by a sealing film 80 that is formed by layering a plurality of layers of thin film, and the sealing film 80 is formed so that the upper layer covers the lower layer; the outer peripheral edge portion of each layer has a portion that is in contact with the base material 60 and that is covered by a resin layer 65 and a protective layer 66 from above the sealing film 80 (see FIG. 7).

Technologies relating to this sealing film include those that have a single-layer structure and those that have a laminated structure. Those that have a single-layer structure can improve their barrier properties by making the film thickness large; however, stress is generated inside of the film when film-forming, and cracks are generated due to such stress, so there is the problem that a good barrier property cannot be obtained. For this reason, the disclosure explains that a stress relaxation layer 81 for relaxing the internal stress of the film is added, and by making this a laminated structure, the internal stress of the barrier layer 82 is relaxed; additionally, by increasing the number of layers, the barrier properties of the sealing film as a whole can be improved (see FIG. 8). Meanwhile, in order to obtain a barrier layer having high barrier properties, the sputtering method or the CVD method are preferably used.

However, the adhesion of a sealing film of a solar cell is required to be long-lasting, at least greater than or equal to 10 years. For this reason, even with sealing film that has good adhesion and with which peeling does not occur immediately after film-forming, there was the problem that, due to water that intrudes inside of the solar cell module, water would intrude into the laminated film of the sealing film, and this causes the sealing film to expand, which causes the film stress to be increased, generating peeling and cracks on the sealing film; therefore, the barrier properties are deteriorated.

### SUMMARY

Therefore, the object of the present invention is to provide a film having stable barrier properties with which peeling will not occur due to change over time by configuring a sealing film that is low-stress and that has low water absorption.

As a result of dedicated research in order to achieve the above-described object, the present inventors found that, by making both the barrier layer and the stress relaxation layer a consistent film-forming process in a vacuum, the problem that foreign matter is easily adhered as described above would not occur; therefore, thickly layering the stress relaxation layer is not necessary. Additionally, by layering the stress relaxation layer and the barrier layer so that they satisfy a certain relationship, the expansion of the sealing film caused by the intrusion of water in a test conducted in an 85° C., 85% RH environment can be prevented, and a sealing film with long-term stability can be provided, thereby completing the present invention.

Therefore, the present invention provides a silicon-containing film comprising a first chemical vapor deposition layer and a second chemical vapor deposition layer that are formed by the plasma CVD method, in which the ratio of the thickness of the first chemical vapor deposition layer (L1) and the thickness of the second chemical vapor deposition layer (L2) L2/L1 is 1.5-9. The first chemical vapor deposition layer comprises elemental silicon, and the oxygen concentration is greater than or equal to 0% by element and less than 10% by element.

The second chemical vapor deposition layer comprises elemental silicon, and the oxygen concentration is greater than 35% by element and less than or equal to 70% by element.

Preferably, the thickness of the first chemical vapor deposition layer (L1) is 5-400 nm, and the thickness of the second chemical vapor deposition layer (L2) is 5-500 nm.

Additionally, a plurality of layers of the first chemical vapor deposition layer and the second chemical vapor deposition layer are preferably formed alternately.

The total thickness of the plurality of first chemical vapor deposition layers is preferably 5n-500 (nm) [n is the number of layers of the first chemical vapor deposition layer].

The layered body of the present invention comprises the above-described silicon-containing film and a base material.

The base material can comprise one electrode film selected from the group consisting of Ag, Al, Mo, ZnO, ITO, BZO, AZO, and GZO.

The present invention also provides an organic electroluminescent element or a thin film solar cell comprising the above-described silicon-containing film.

The present invention provides a silicon-based thin film having stable barrier properties with which peeling will not occur due to change over time, which realizes a sealing film structure that is low-stress and with low water absorption, as well as a method to form the silicon-based thin film.

### BRIEF DESCRIPTION OF THE DRAWINGS

FIG. 1 is a diagram schematically showing a layered body 1A comprising a silicon-containing film 100 according to one embodiment of the present invention.

FIG. 2 is a diagram schematically showing a layered body 1B comprising a silicon-containing film 200 according to another embodiment of the present invention.

FIG. 3 is a diagram schematically showing a layered body 1C comprising a silicon-containing film 300 according to yet another embodiment of the present invention.

FIG. 4 is a schematic diagram of the lateral cross-section of a film forming device 30.

FIG. 5 is a schematic diagram of the film forming device 30, as seen from above.

FIG. 6 is a diagram schematically showing a cross section of a thin film solar cell 20 according to one embodiment of the present invention.

FIG. 7 is a cross-sectional view of a conventional solar cell module 600.

FIG. 8 is an enlarged cross-sectional view of a boundary portion of a conventional base material and solar cell.

### DETAILED DESCRIPTION OF EMBODIMENTS

(1) Silicon-Containing Film

The silicon-containing film of the present invention is formed by the plasma CVD method and comprises a first chemical vapor deposition layer and a second chemical vapor deposition layer formed by the plasma CVD method. A plurality of layers (n layers) of the first chemical vapor deposition layer and the second chemical vapor deposition layer may be alternately provided. The n is an integer greater than or equal to one and, preferably, may be an integer of 1-10 and, more preferably, an integer of 1-7. Additionally, another layer may be formed between the first chemical vapor deposition layer and the second chemical vapor deposition layer. Specifically, when n is seven, the silicon-containing film comprises seven layers of both the first chemical vapor deposition layer and the second chemical vapor deposition layer, which are alternately provided (7 layers/7 layers). Also, n layers of a stress relaxation layer and n+1 layers of a barrier layer can be alternately layered and can also take a form in which one layer of a stress relaxation layer is layered for every two layers of a barrier layer. Additionally, n+1 layers of a stress relaxation layer and n layers of a barrier layer can be alternately layered and can take a form in which one layer of the barrier layer is layered for every two layers of the stress relaxation layer.

(1-1) First Chemical Vapor Deposition Layer

The first chemical vapor deposition layer (hereinafter, this is sometimes referred to as the stress relaxation layer) comprises elemental silicon, and the oxygen concentration is greater than or equal to 0% by element and less than 10% by element. The stress relaxation layer may comprise carbon atoms in addition to silicon atoms and oxygen atoms. In the present invention, the composition of the stress relaxation layer may be less than 10% by element of oxygen atoms, 10-20% by element of silicon atoms, and 20-35% by element of carbon atoms. Additionally, the composition can comprise, for example, 30-55% by element of hydrogen atoms. The composition can comprise, for example, less than or equal to 10% by element (around 0-10% by element) of hydrogen atoms.

The thickness of a single layer of the stress relaxation layer may be less than or equal to 1 μm and, preferably, may be less than or equal to 600 nm and, more preferably, less than or equal to 400 nm (for example, 5-400 nm). When the thickness of a single layer of the stress relaxation layer exceeds 1 μm, the water absorption amount becomes large, making the layer become prone to peeling.

When there is a plurality of layers of the stress relaxation layer, the total thickness of all of the stress relaxation layers is, for example, less than or equal to 1 μm; preferably, the thickness is less than or equal to 400 nm (for example, 5-400 nm) and, more preferably, 5-100 nm. The total thickness of the plurality of layers of the stress relaxation layer may be 5n-500 (nm) [n is the number of layers of the stress relaxation layer, and n is an integer greater than or equal to one]. The n is the same as that described above. For example, when the silicon-containing film comprises two layers of the stress relaxation layer, the thickness of one layer of the stress relaxation layer may each be around 200 nm. Additionally, for example, one layer may be around 50 nm, and the other layer may be around 300 nm. When there is a plurality of layers of the stress relaxation layer, it is preferable for the thickness of each layer is preferably about the same. When the total thickness of the stress relaxation layers exceeds 1 μm, the amount of water absorption becomes large, making the layers become prone to peeling.

(1-2) Second Chemical Vapor Deposition Layer

The second chemical vapor deposition layer (hereinafter, this is sometimes referred to as the barrier layer) comprises elemental silicon, and the oxygen concentration is greater than 35% by element and less than or equal to 70% by element. The barrier layer may be configured so that there are 60-70% by element of oxygen atoms and 30-35% by element of silicon atoms. Additionally, the composition can comprise carbon atoms. The composition can also comprise less than or equal to 5% by element (around 0-5% by element) hydrogen atoms. The composition does not need to comprise nitrogen atoms.

The thickness of a single layer of the barrier layer may be less than or equal to 1 μm and, preferably, may be less than or equal to 700 nm and, more preferably, less than or equal to 500 nm (for example, 5-500 nm). When the thickness of a single layer of the barrier layer exceeds 1 μm, the layer becomes prone to breaking. When there is a plurality of layers of the barrier layer, the total thickness of all of the barrier layers is, for example, less than or equal to 1 μm; preferably, the thickness is less than or equal to 700 nm, more preferably, the thickness is less than or equal to 500 nm, and, even more preferably, the thickness is less than or equal to 400 nm (for example, 100-400 nm). When there is a plurality of layers of the barrier layer, the total thickness of all the barrier layers is not particularly limited.

(1-3) The ratio L2/L1 of the thickness of the first chemical vapor deposition layer (L1) and the thickness of the second chemical vapor deposition layer (L2)

In the silicon-containing film of the present invention, the ratio L2/L1 of the thickness of the first chemical vapor deposition layer (L1) and the thickness of the second chemical vapor deposition layer (L2) is 1.5-9. With L2/L1 in this range, the invention can be made to be low-stress, and the absorption of moisture can be reduced. L2/L1 is preferably 1.8-8 and, more preferably, is 2.5-8. L1 and L2 may be the thickness of a single layer, or they may be the total thickness as well.

(1-4) Method of Measuring the Oxygen Atom Concentration

In the present invention, the concentration of oxygen atoms in each of the above-described layers and film can be determined by Rutherford backscattering spectroscopy (RBS) and compositional analysis using hydrogen forward scattering analysis (HFS). The concentration of silicon atoms and carbon atoms can be measured in the same way. Regarding the hydrogen atoms, since they cannot be analyzed using RBS, they are measured using HFS.

In RBS, fast ions (He⁺, H⁺, etc.) are irradiated on the sample, and the energy and yield of the scattered ions are measured regarding a part of the incident ions that have undergone elastic (Rutherford) scattering by the nuclei in the sample. The energy of the scattered ions is different depending on the mass and the location (the depth) of the target atoms, so that the elemental composition of the sample in the depth direction can be obtained from the energy and the yield of these scattered ions. In HFS, by utilizing the fact that the hydrogen in the sample will be scattered forward due to elastic recoil by irradiating fast ions (He⁺) on the sample, the depth distribution of hydrogen is obtained from the energy and the yield of this recoiled hydrogen.

Regarding the concentration of oxygen atoms in each layer and film, the concentration of oxygen atoms can be controlled to be within a prescribed range and is formed by adjusting the supplied gas and the plasma power (the applied power) in the plasma CVD method. Organic silicon compounds comprising oxygen atoms can be used as the raw material gas. Specific examples include HMDSO by itself, HMDSO+Ar/H₂, HMDSO+O₂, HMDSO+HMDS, HMDS+O₂, etc.

Table 1 below shows an example of a composition of the barrier layer, the stress relaxation layer, and a base film mentioned below of the silicon-containing film of the present invention.

TABLE 1

| | Constituent elements (unit: % by element) | | | | |
|---|---|---|---|---|---|
| | Si | H | C | N | O |
| Barrier layer | 30-35 | less than or | 0 | 0 | 60-70 |
| | | equal to 5 | | | |
| Stress | 10-20 | 30-55 | 20-35 | less than or | less than or |
| relaxation layer | | | | equal to 10 | equal to 10 |
| Base film | 10-30 | 10-50 | 10-30 | 0 | 10-35 |

(2) Layered Body

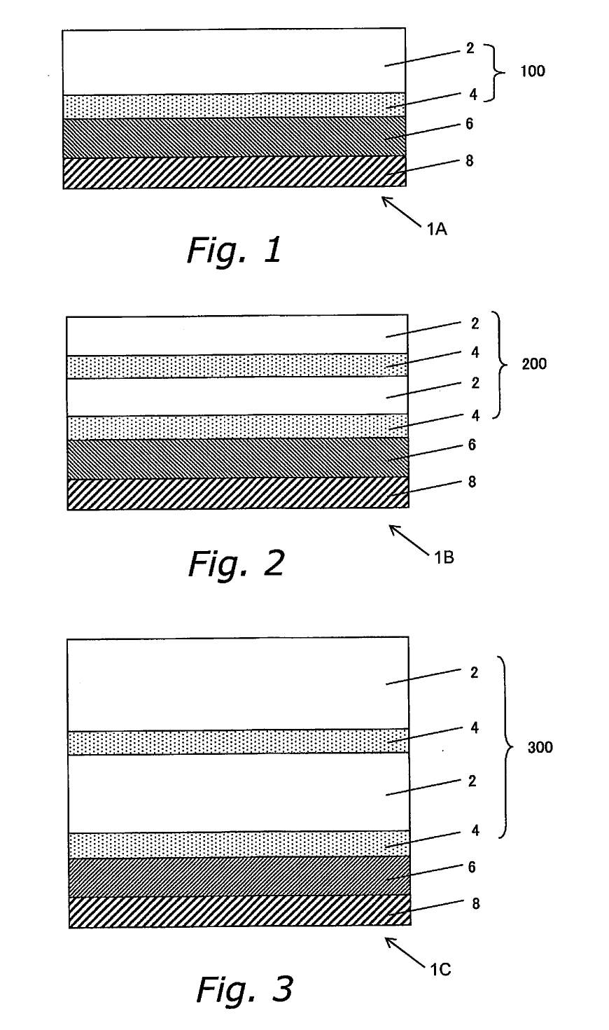

FIGS. 1-3 schematically show layered bodies 1A, 1B, and 1C each comprising silicon-containing films 100, 200, and 300 according to one embodiment of the present invention. In the layered body 1A in FIG. 1, the silicon-containing film 100 is configured by each single layer of the stress relaxation layer 4 and the barrier layer 2. The number 8 is a base material, and a base film 6, a stress relaxation layer 4, and a barrier layer 2 are layered on this base material in this order. In the layered bodies 1B and 1C in FIGS. 2 and 3, the silicon-containing film 200 and 300 are configured by two alternating layers of a stress relaxation layer 4 and a barrier layer 2. Additionally, a base film 6, a stress relaxation layer 4, a barrier layer 2, a stress relaxation layer 4, and a barrier layer 2 are layered on a base material 8 in this order. When compared to the layered body 1B, the layered body 1C shows an example in which the thickness of the barrier layer is large. In the layered body, a base film does not have to be provided. Also, the layering order of the stress relaxation layer and the barrier layer is arbitrary; a barrier layer may be layered on the base material, and the stress relaxation layer may be layered on that, or the order can also be reversed.

For the layered body of the present invention, for example, the configurations below, in which a stress relaxation layer and a barrier layer are alternately layered, can be exemplified.
(i) base material/(base film: does not have to be provided. henceforth, the same)/stress relaxation layer/barrier layer/ . . . /stress relaxation layer/barrier layer
(ii) base material/(base film)/barrier layer/stress relaxation layer/ . . . /stress relaxation layer/barrier layer
(iii) base material/(base film)/stress relaxation layer/barrier layer/ . . . /barrier layer/stress relaxation layer
(iv) base material/(base film)/barrier layer/stress relaxation layer/ . . . /barrier layer/stress relaxation layer

(2-1) Base Material

Examples of the above-described base material include a film consisting of organic substances, a film consisting of inorganic substances, and a film comprising both organic substances and inorganic substances. An example of an organic substance in a base material is a polymer film such as PET film, etc. Additionally, examples of inorganic substances include electrode film of Ag, Al, Mo, ZnO, ITO, BZO, AZO, and GZO, etc.

(2-2) Base Film

Examples of the above-described base film include a film that is formed by the plasma CVD method and comprise at least silicon atoms and oxygen atoms, whose oxygen atom concentration is 10-35% by element, etc. The base film can be mainly provided in order to improve the adhesion between the silicon-containing film and the base material.

(3) Manufacturing Method for the Layered Body

The manufacturing method for the above-described layered body may comprise a first step in which a base film is formed on the base material by the plasma CVD method using a raw material gas consisting of an organic silicon compound comprising oxygen atoms; a second step in which a first chemical vapor deposited film is formed on the base film formed in the first step by the plasma CVD method using a raw material gas consisting of a compound comprising an organic silicon compound and hydrogen atoms; and a third step in which a second chemical vapor deposited film is formed by the plasma CVD method using a raw material gas consisting of a compound comprising an organic silicon compound and oxygen atoms. By alternately conducting the second and third steps a plurality of times, a layered body in which a plurality of layers of the first chemical vapor deposited layer and the second chemical vapor deposited layer are alternately layered can be obtained. The first step does not have to be conducted, and a second chemical vapor deposition layer may be first formed by the third step; the second step may be conducted thereafter.

In the above-described second and third steps, using an organic silicon compound that does not comprise oxygen atoms is preferable. Additionally, the organic silicon compound comprising oxygen atoms are preferably hexamethyldisilazane, and the organic silicon compound that does not comprise oxygen atoms are preferably hexamethyldisiloxane.

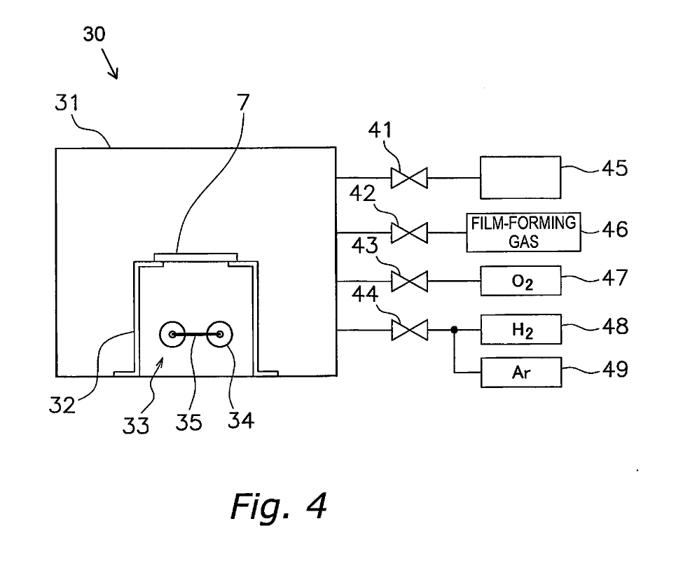

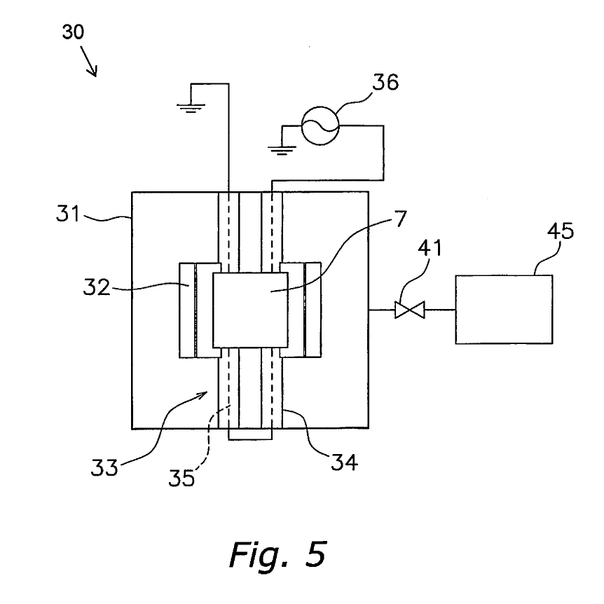

FIG. 4 (the lateral cross-sectional view) and FIG. 5 (the plan view) show a block diagram of a film forming device. A vacuum chamber, which is a film deposition chamber 31, an exhaust system 45 comprising a rotary pump and a turbo-molecular pump, a high-frequency power source 36 for generating plasma, and a flange for introducing various gases are disposed in the film forming device 30.

The film deposition chamber 31 is connected to the exhaust system 45, a film-forming gas tank 46, an O₂ supply tank 47, an H₂ supply tank 48, and an Ar supply tank 49. The exhaust system 45 is connected to the film deposition chamber 31 via a flow rate control valve 41. The film-forming gas tank 46 is connected to the film deposition chamber 31 via a flow rate control valve 42, the O₂ supply tank 47 via a flow rate control valve 43, and the H₂ supply tank 48 and the Ar supply tank 49 via a flow rate control valve 44. A loop antenna 33 is provided inside of the film deposition chamber 31.

The loop antenna 33 is a means for generating plasma and is configured by an insulating tube 34 and a conductive electrode 35. Two insulating tubes 34 are disposed in parallel opposing each other in the film deposition chamber 31. The conductive electrode 35 is inserted in the two insulating tubes 34 and extends through the opposing side walls of the film deposition chamber 31 in order to take on a nearly U-shape in the plan view, as shown in FIG. 5; the electrode is also connected to the high-frequency power source 36 that supplies a high-frequency current. The frequency of the high-frequency current is preferably 13.56 MHz. Meanwhile, the plasma to be used may be CCP, ICP, a barrier discharge, a hollow discharge, etc.

After disposing a base material 7 on which the film is formed onto a fixed base 32 of the base material so that the deposition surface faces the loop antenna 33 side, the internal pressure of the film deposition chamber 31 is depressurized to be preferably less than or equal to 9.9×10⁻⁵ Pa with the exhaust system 45.

After decompression inside of the film deposition chamber 31 has been completed, the raw material gas is introduced in the film deposition chamber 31 by opening the flow rate control valves 42-44. The raw material gas can be appropriately selected so that the base film comprises at least silicon atoms and oxygen atoms and so that the concentration of the oxygen atoms will be, for example, 10-35% by element. Specific examples of the raw material gas include HMDSO gas by itself, HMDSO+Ar/H₂, HMDSO+O₂, HMDSO+HMDS, HMDS+O₂, etc. Of the above, HMDSO by itself is preferable. The rate of introduction of the gas may be 3 sccm-45 sccm.

Next, a high-frequency current flows from the high-frequency power source 36 to the loop antenna 33, and plasma is generated in the periphery of the loop antenna 33. The plasma power at this time may be 1 kW-10 kW. A surface reaction takes place on the surface of the base material, and a base film is formed on the base material 7. After a prescribed amount of time has elapsed, the introduction of gas is stopped by closing the flow rate control valves 42-44.

After forming the base film, for example, the first chemical vapor deposited layer (the stress relaxation layer) is formed in the same way as described above. Meanwhile, the base film does not have to be formed; in that case, the stress relaxation layer is formed on the base material. First, the flow rate control valve 44 is opened, and, for example, a mixed gas of H₂ gas and Ar gas is introduced in the film deposition chamber 31. At the same time, raw material gas of HMDS gas, etc., is introduced with the flow rate control valve 42. The rate of introduction of each gas at this time may be 20 sccm-40 sccm for the mixed gas of H₂ gas and Ar gas and 3 sccm-20 sccm for the HMDS gas. Next, a high-frequency current flows from the high-frequency power source 36 to the loop antenna 33 so that the plasma power will be 0.1 kW-10 kW, and plasma is generated in the periphery of the loop antenna 33.

A surface reaction takes place on the surface of the base material, and a stress relaxation layer 4 is formed as to cover the base film 6, as shown in FIGS. 1-3. After a prescribed amount of time has elapsed, the introduction of gas is stopped by closing the flow rate control valves 42 and 44.

After forming the stress relaxation layer, the second chemical vapor deposited layer (the barrier layer) is formed in the same way as described above. First, the flow rate control valve 43 is opened, and, for example, O₂ gas is introduced in the film deposition chamber 31. At the same time, raw material gas of HMDS gas, etc., is introduced with the flow rate control valve 42. The rate of introduction of each gas at this time may be, for example, 20 sccm-1000 sccm for O₂ gas and 3 sccm-20 sccm for the HMDS gas. Next, a high-frequency current flows from the high-frequency power source 36 to the loop antenna 33 so that the plasma power will be 0.1 kW-8 kW, and plasma is generated in the periphery of the loop antenna 33.

A surface reaction takes place on the surface of the base material, and a barrier layer 2 (for example, a silicon oxide film) is formed so as to cover the stress relaxation layer 4, as shown in FIGS. 1-3. After a prescribed amount of time has elapsed, the introduction of gas is stopped by closing the flow rate control valves 42 and 43. This silicon oxide film preferably comprises Si and O at a composition ratio of Si:O=1:1.9-2.1.

The process conducted for the above-described stress relaxation layer 4 and the barrier layer 2 is repeated n times (n is, for example, n=7 in the same way as described above). As a result, as shown in FIGS. 1-3, a base film 6 is layered on the base material, and an n-step silicon-containing film, in which a silicon oxide film (the barrier layer 2) is layered on a stress relaxation layer 4 comprising silicon, is formed thereon.

As described above, first, HMDSO gas, etc., is used as the raw material gas, and a base film 6 is formed on the base material by the plasma CVD method; next, a stress relaxation layer 4 is formed on the base film 6 using HMDS gas, HMDSO gas, etc. A barrier layer is also formed on the stress relaxation layer 4 using HMDS gas, HMDSO gas, etc. Meanwhile, here, film formation in the order of the base film, the stress relaxation layer, and the barrier layer was shown; however, the stress relaxation layer can also be formed on the barrier layer after forming the barrier layer on base film or the base material. Additionally, a silicon nitride film may be layered between each of the layers as an intermediate layer, using NH₃ gas and SiH₄ gas, etc.

The method of the present invention does not use an etching process, etc., unlike the prior art; therefore, the invention will not damage the base materials such as a solar cell. Additionally, the silicon-containing film comprising the stress relaxation layer 4 and the barrier layer 2 has a function to protect the base materials, such as a solar cell, from plasma energy as vapor phase growth occurs chemically on the base material 7, so that damage to the device by plasma energy can be reduced. Also, since the formation of the stress relaxation layer 4 and the barrier layer 2 takes place in the same chamber (the film deposition chamber 31), the structure of the device can be simplified. Also, since the exchange of vacuum and air is not required, steps such as vacuuming and opening to the air are not necessary, and the possibility that foreign matter will float in and the foreign matter will adhere to the base material due to the air that flows in and out in order to change the ambient environment is low; therefore, covering the foreign matter is unnecessary, and, thus, thickly layering the organic film is likely unnecessary.

(4) Organic Electroluminescent Element or Thin Film Solar Cell

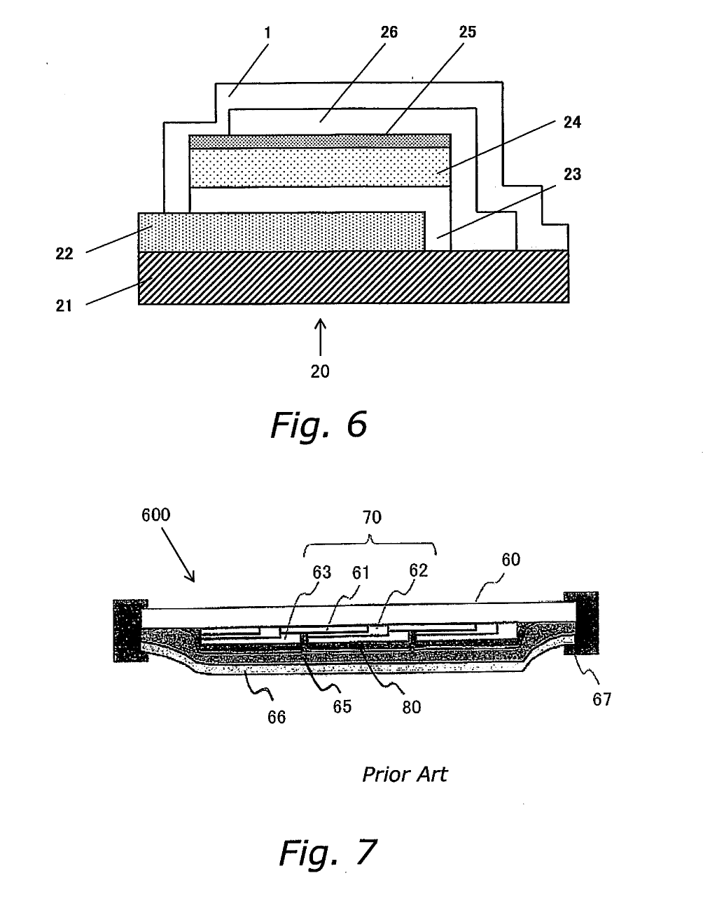

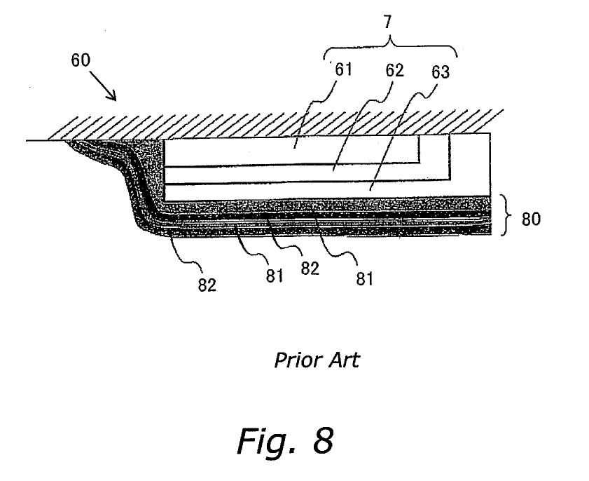

FIG. 6 schematically shows a cross section of a thin film solar cell 20 according to one embodiment of the present invention; 21 is a plastic base material, and 22 is an ITO electrode. 23 is a phthalocyanine deposited film, and 24 is a fullerene vapor deposited film. 25 is a LiF layer, and 26 is an Ag electrode. A silicon-containing film 1 is layered on a base material comprising these organic substances and inorganic substances.

The organic EL element or the thin film solar cell of the present invention comprises the silicon-containing film of the present invention. The silicon-containing film of the present invention has excellent adhesion over time with a transparent conducting film and a metal film that exist in organic EL elements and solar cells, etc.; since the barrier layer is rarely broken, there is excellent stability over time under high-temperature and high-humidity conductions.

### EXAMPLES

The present invention is described in further detail below based on examples, but the present invention is not limited by these examples.

### Example 1

An Ag layer with a thickness of 200 nm was formed on a part of the surface of a glass base material. This base material was disposed on a base material fixed base in a film deposition chamber so that the surface having the Ag layer faces the loop antenna side. Next, the internal pressure of the film deposition chamber was depressurized to become less than or equal to 9.9×10⁻⁵ Pa using an exhaust system. After the decompression inside of the film deposition chamber was completed, HMDSO gas was introduced into the film deposition chamber. The rate of introduction of the HMDSO gas was 3 scccm-45 sccm.

Next, a high-frequency current flowed from a high-frequency power source to the loop antenna. The plasma power at this time was 1 kW-10 kW. A surface reaction took place on the surface of the base material, and a base film that covers the plastic film was formed. One minute later, the flow rate control valve was closed in order to stop the introduction of the HMDSO gas.

After forming the base film, a forming process for the stress relaxation layer using HMDS gas was carried out. The rate of introduction of HMDS gas at this time was 3 sccm-20 sccm, and the plasma power was 0.1 kW-10 kW.

After forming the stress relaxation layer, a barrier layer was formed using HMDS gas in the same way as described above. The rate of introduction of HMDS gas at this time was 3 sccm-20 sccm, and the plasma power was 0.1 kW-10 kW. This silicon oxide film had a composition ratio of Si and O of Si:O=1:1.9-2.1.

The formation process of the stress relaxation layer and the barrier layer was repeated seven times. As a result, as shown in Table 2, a layered body was obtained in which a silicon-containing film (a seven step alternate layering of a stress relaxation layer with a film thickness of 30 nm and a barrier layer with a film thickness of 60 nm) was layered on a base film.

### Examples 2-5, Comparative Samples 1-8

In Example 1, besides changing the film thickness and the number of layers of the stress relaxation layer and the barrier layer as shown in Table 2, each of the layered bodies was obtained in the same way as in Example 1. A barrier layer was not provided in Comparative Examples 2 and 5.

Evaluation of Peeling Immediately After Film Formation

The state of peeling immediately after the film forming of the layered bodies obtained in Examples 1-5 and Comparative Examples 1-8 was visually observed. The results were evaluated by the following criteria. The results are shown in Table 2.
◯: lifting or peeling of the silicon-containing film was not observed
×: lifting or peeling of the silicon-containing film was observed

As a result of the above-described test, lifting and peeling of the silicon-containing film was observed in the layered bodies of Comparative Example 1 and 4. Lifting and peeling of the silicon-containing film was not observed in the other layered bodies.

Accelerated Test

The layered bodies obtained in Examples 1-5 and Comparative Examples 2, 3, and 5-8 were left in an environment of 85° C., 85% RH in order to conduct an accelerated test. The state of peeling the silicon-containing film from the base material immediately after film-forming, 500 hours, and 1000 hours after the accelerated test was visually observed. The results were evaluated by the following criteria. The results are shown in Table 2.
◯: lifting or peeling of the silicon-containing film was not observed
Δ: peeling was observed here and there
×: the entire surface peeled

TABLE 2

| | | | | | After | Total film | Total film |
|---|---|---|---|---|---|---|---|
| | | | Immediately | After | accelerated test | thickness (nm) | thickness (nm) |
| | | | after film- | accelerated test | (1000 hours | of the stress | of the silicon- |
| | Stress relaxation layer/Barrier layer | L2/L1 | forming | (500 hours later) | later) | relaxation layer | containing film |
| Example 1 | 30 nm × 7 layers/60 nm × 7 layers | 2 | ◯ | Δ | Δ | 210 | 630 |
| Example 2 | 50 nm × 7 layers/120 nm × 7 layers | 2.4 | ◯ | ◯ | Δ | 350 | 1190 |
| Example 3 | 60 nm × 1 layer/180 nm × 1 layer | 3 | ◯ | ◯ | ◯ | 60 | 240 |
| Example 4 | 60 nm × 1 layer/360 nm × 1 layer | 6 | ◯ | ◯ | ◯ | 60 | 420 |
| Example 5 | 8 nm × 7 layers/60 nm × 7 layers | 7.5 | ◯ | ◯ | ◯ | 56 | 476 |
| Comparative | 400 nm × 1 layer/550 nm × 1 layer | 1.4 | X | — | — | 400 | 950 |
| Example 1 | | | | | | | |
| Comparative | 210 nm × 1 layer/none | 0 | ◯ | X | — | 210 | 210 |
| Example 2 | | | | | | | |
| Comparative | 420 nm × 1 layer/450 nm × 1 layer | 1.1 | ◯ | X | — | 420 | 870 |
| Example 3 | | | | | | | |
| Comparative | 60 nm × 1 layer/550 nm × 1 layer | 9.2 | X | — | — | 60 | 610 |
| Example 4 | | | | | | | |
| Comparative | 420 nm × 1 layer/none | 0 | ◯ | X | — | 420 | 420 |
| Example 5 | | | | | | | |
| Comparative | 420 nm × 1 layer/120 nm × 1 layer | 0.3 | ◯ | X | — | 420 | 540 |
| Example 6 | | | | | | | |
| Comparative | 60 nm × 3 layers/60 nm × 3 layers | 1 | ◯ | X | — | 180 | 360 |
| Example 7 | | | | | | | |
| Comparative | 60 nm × 7 layers/60 nm × 7 layers | 1 | ◯ | X | — | 420 | 840 |
| Example 8 | | | | | | | |

*L2/L1 = (thickness of the barrier layer)/(thickness of stress relaxation layer)

As shown in Table 2, in the silicon-containing film of the example in which the ratio L2/L1 of the thickness of the barrier layer (L2) and the thickness of the stress relaxation layer (L1) is 1.5-9, the peeling resistance after the accelerated test was good. Meanwhile, in the layered body of Comparative Example 1, cracking occurred when the thickness of the barrier layer was greater than or equal to 500 nm. The silicon-containing film of the Example has an excellent peeling resistance even after the accelerated test and displays high barrier properties over a long period of time.

A barrier film that does not display peeling over a long period of time, with respect to a base material in which specifically organic substances (an organic-based power generation layer, a light emitting layer, a plastic film (PET and PEN), etc.) and inorganic substances (a transparent conductive film, metal electrodes, an inorganic-based power generation layer, etc.) are mixed and exposed on the surface, such as organic EL elements and solar cells, etc., which are easily deteriorated by moisture and oxygen, can be formed without damaging the base material.

1. A silicon-containing film, comprising:
a first chemical vapor deposition layer including elemental silicon, the first chemical vapor deposition layer being formed by a plasma CVD method such that oxygen concentration is greater than or equal to 0% by element and less than 10% by element; and
a second chemical vapor deposition layer including elemental silicon, the second chemical vapor deposition layer being formed by the plasma CVD method such that oxygen concentration is greater than 35% by element and less than or equal to 70% by element,
a ratio of the thickness of the second chemical vapor deposition layer relative to the thickness of the first chemical vapor deposition layer being 1.5-9.

2. The silicon-containing film recited in claim 1, wherein
the thickness of the first chemical vapor deposition layer is 5-400 nm, and
the thickness of the second chemical vapor deposition layer is 5-500 nm.

3. The silicon-containing film recited in claim 1, wherein
a plurality of layers of the first chemical vapor deposition layer and a plurality of layers of the second chemical vapor deposition layer are alternately formed.

4. The silicon-containing film recited in claim 3, wherein
the total thickness of the plurality of the layers of the first chemical vapor deposition layer is 5n-500 nm, where n is the number of layers of the first chemical vapor deposition layer.

5. A layered body comprising:
the silicon-containing film recited in claim 1; and
a base material.

6. The layered body recited in claim 5, wherein
the base material includes an electrode film selected from the group consisting of Ag, Al, Mo, ZnO, ITO, BZO, AZO, and GZO.

7. An organic EL element comprising:
the silicon-containing film recited in claim 1.

8. The silicon-containing film recited in claim 2, wherein
a plurality of layers of the first chemical vapor deposition layer and a plurality of layers of the second chemical vapor deposition layer are alternately formed.

9. The silicon-containing film recited in claim 8, wherein
the total thickness of the plurality of the layers of the first chemical vapor deposition layer is 5n-500 (nm), where n is the number of layers of the first chemical vapor deposition layer.

10. A layered body comprising:
the silicon-containing film recited in claim 2; and
a base material.

11. The layered body recited in claim 10, wherein
the base material includes an electrode film selected from the group consisting of Ag, Al, Mo, ZnO, ITO, BZO, AZO, and GZO.

12. A layered body comprising:
the silicon-containing film recited in claim 3; and
a base material.

13. The layered body recited in claim 12, wherein
the base material includes an electrode film selected from the group consisting of Ag, Al, Mo, ZnO, ITO, BZO, AZO, and GZO.

14. A layered body comprising:
the silicon-containing film recited in claim 4; and
a base material.

15. The layered body recited in claim 14, wherein
the base material includes an electrode film selected from the group consisting of Ag, Al, Mo, ZnO, ITO, BZO, AZO, and GZO.

16. A layered body comprising:
the silicon-containing film recited in claim 8; and
a base material.

17. The layered body recited in claim 16, wherein
the base material includes an electrode film selected from the group consisting of Ag, Al, Mo, ZnO, ITO, BZO, AZO, and GZO.

18. A layered body comprising:
the silicon-containing film recited in claim 9; and
a base material.

19. The layered body recited in claim 18, wherein
the base material includes an electrode film selected from the group consisting of Ag, Al, Mo, ZnO, ITO, BZO, AZO, and GZO.

20. A thin film solar cell comprising:
the silicon-containing film recited in claim 1.
